(19) United States
(12) Patent Application Publication
(10) Pub. No.: US 2019/0154953 A1
(43) Pub. Date: May 23, 2019

(54) CONTROL APPARATUS, CONTROL SYSTEM, AND CONTROL METHOD

(71) Applicant: SONY CORPORATION, TOKYO (JP)

(72) Inventors: YUKI SUGIE, KANAGAWA (JP); DAISUKE KIKUCHI, KANAGAWA (JP); HIROSHI ICHIKI, KANAGAWA (JP); TSUNEO HAYASHI, TOKYO (JP); MASAYOSHI AKITA, TOKYO (JP); MITSUNORI UEDA, TOKYO (JP); AKIO FURUKAWA, TOKYO (JP)

(73) Assignee: SONY CORPORATION, TOKYO (JP)

(21) Appl. No.: 16/308,525

(22) PCT Filed: Mar. 24, 2017
(86) PCT No.: PCT/JP2017/011939

§ 371 Date: Dec. 10, 2018

(30) Foreign Application Priority Data
Jun. 23, 2016 (JP) 2016-124423

(51) Int. Cl. G02B 7/04; G11B 7/126; G03F 7/20

(52) U.S. Cl. CPC G02B 7/04; G03F 7/2002; G11B 7/126

(57) ABSTRACT

[Object] To propose a control apparatus, a control system and a control method which are capable of appropriately determining an irradiation period in a scene in which light is radiated at the same time as imaging.

[Solution] A control apparatus including: a light source control unit configured to determine a period in accordance with a period between an exposure start timing of a first line in an image pickup element and an exposure end timing of a second line in the image pickup element as an irradiation period during which a light source unit is caused to radiate light. The second line is a line in which start of exposure in one frame is earlier than in the first line.

### TECHNICAL FIELD

The present disclosure relates to a control apparatus, a control system, and a control method.

### BACKGROUND ART

In related art, an image pickup element having a rolling shutter mechanism, such as, for example, a complementary metal oxide semiconductor (CMOS) is widespread. Readout of pixels at such an image pickup element is executed, for example, while being delayed by a predetermined time period for each line.

Further, the following Patent Literature 1 discloses a technology of causing a light source unit to radiate light at the same time as imaging.

### CITATION LIST

### Patent Literature

Patent Literature 1: JP 2014-124331A

### DISCLOSURE OF INVENTION

### Technical Problem

However, Patent Literature 1 fails to disclose a method for determining a length of an irradiation period. Therefore, there is a possibility that the length of the irradiation period is improperly set with the technology disclosed in Patent Literature 1.

Therefore, the present disclosure proposes a new and improved control apparatus, control system and control method which are capable of appropriately determining an irradiation period in a scene in which light is radiated at the same time as imaging.

### Solution to Problem

According to the present disclosure, there is provided a control apparatus including: a light source control unit configured to determine a period in accordance with a period between an exposure start timing of a first line in an image pickup element and an exposure end timing of a second line in the image pickup element as an irradiation period during which a light source unit is caused to radiate light. The second line is a line in which start of exposure in one frame is earlier than in the first line.

In addition, according to the present disclosure, there is provided a control system including: a light source unit; an image pickup unit; and a light source control unit configured to determine a period in accordance with a period between an exposure start timing of a first line in an image pickup element included in the image pickup unit and an exposure end timing of a second line in the image pickup element as an irradiation period during which the light source unit is caused to radiate light. The second line is a line in which start of exposure in one frame is earlier than in the first line.

In addition, according to the present disclosure, there is provided a control method including: determining, by a processor, a period in accordance with a period between an exposure start timing of a first line in an image pickup element and an exposure end timing of a second line in the image pickup element as an irradiation period during which a light source unit is caused to radiate light. The second line is a line in which start of exposure in one frame is earlier than in the first line.

### Advantageous Effects of Invention

As described above, according to the present disclosure, it is possible to appropriately determine an irradiation period in a scene in which light is radiated at the same time as imaging. Note that effects described here are not necessarily limitative, and may be any effect disclosed in the present disclosure.

### BRIEF DESCRIPTION OF DRAWINGS

FIG. 1 is an explanatory diagram illustrating a configuration example of a control system according to an embodiment of the present disclosure.

FIG. 2 is a functional block diagram illustrating a configuration example of a camera head 105 according to the embodiment.

FIG. 3 is an explanatory diagram illustrating a problem in a publicly known technology.

FIG. 4 is a functional block diagram illustrating a configuration example of a CCU 139 according to the embodiment.

FIG. 5A is an explanatory diagram illustrating an example of determination of a top line and a bottom line according to the embodiment.

FIG. 5B is an explanatory diagram illustrating an example of determination of the top line and the bottom line according to the embodiment.

FIG. 6 is an explanatory diagram illustrating an example of determination of an irradiation period according to the embodiment.

FIG. 7 is an explanatory diagram illustrating a control example of irradiation of light according to the embodiment.

FIG. 8 is a diagram illustrating a list of characteristics for each type of light sources.

FIG. 9 is a flowchart illustrating an operation example according to the embodiment.

FIG. 10 is a view depicting an example of a schematic configuration of a microscopic surgery system.

FIG. 11 is a view illustrating a state of surgery in which the microscopic surgery system depicted in FIG. 10 is used.

### MODE(S) FOR CARRYING OUT THE INVENTION

Hereinafter, a preferred embodiment of the present disclosure will be described in detail with reference to the appended drawings. Note that, in this specification and the appended drawings, structural elements that have substantially the same function and structure are denoted with the same reference numerals, and repeated explanation of these structural elements is omitted.

Further, in the present specification and drawings, there is a case where a plurality of components having substantially the same functional configuration are distinguished by different alphabetical characters being assigned after the same reference numeral. For example, a plurality of components having substantially the same functional configuration are distinguished as necessary as an endoscope 101a and an endoscope 101b. However, in the case where it is not necessary to particularly distinguish among a plurality of components having substantially the same functional configuration, only the same reference numeral is assigned. For example, in the case where it is not necessary to particularly distinguish between the endoscope 101a and the endoscope 101b, they are simply referred to as an endoscope 101.

Further, “Mode(s) for Carrying Out the Invention” will be described in accordance with the following item order.

1. Configuration of control system
2. Detailed description of embodiment
3. Application examples
4. Modified examples

### 1. CONFIGURATION OF CONTROL SYSTEM

A control system according to an embodiment of the present disclosure can be applied to a wide range of systems such as, for example, an endoscopic surgery system 10. In the following description, an example where the control system is applied to the endoscopic surgery system 10 will be mainly described.

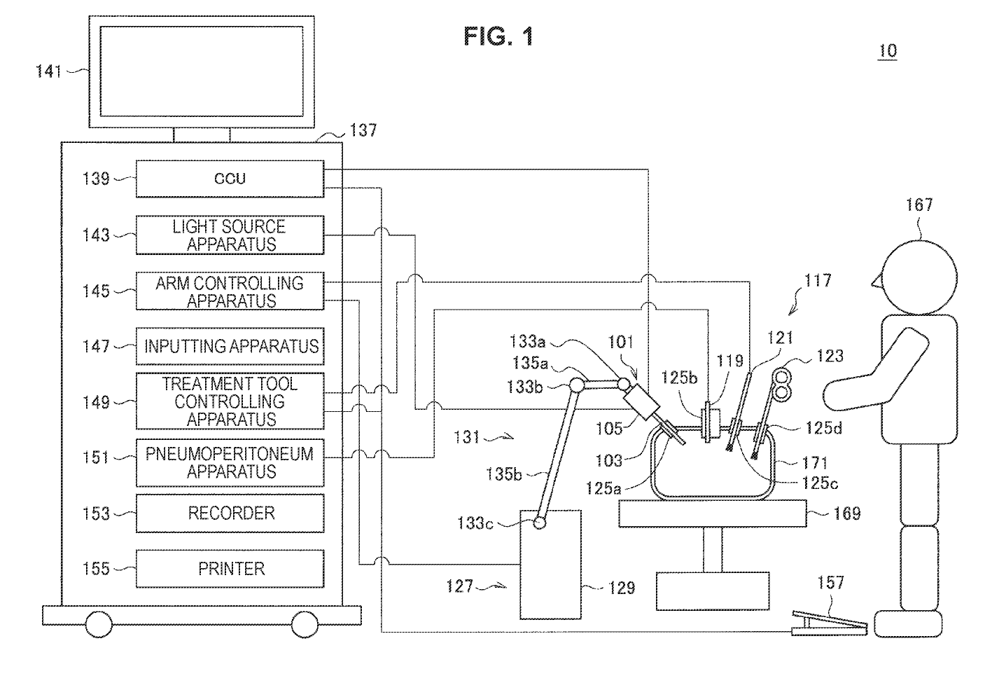

FIG. 1 is a view depicting an example of a schematic configuration of an endoscopic surgery system 10. In FIG. 1, a state is illustrated in which a surgeon (medical doctor) 167 is using the endoscopic surgery system 10 to perform surgery for a patient 171 on a patient bed 169. As depicted, the endoscopic surgery system 10 includes an endoscope 101, other surgical tools 117, a supporting arm apparatus 127 which supports the endoscope 101 thereon, and a cart 137 on which various apparatuses for endoscopic surgery are mounted.

In endoscopic surgery, in place of incision of the abdominal wall to perform laparotomy, a plurality of tubular aperture devices called trocars 125a to 125d are used to puncture the abdominal wall. Then, a lens barrel 103 of the endoscope 101 and the other surgical tools 117 are inserted into body lumens of the patient 171 through the trocars 125a to 125d. In the example depicted, as the other surgical tools 117, a pneumoperitoneum tube 119, an energy treatment tool 121 and forceps 123 are inserted into body lumens of the patient 171. Further, the energy treatment tool 121 is a treatment tool for performing incision and peeling of a tissue, sealing of a blood vessel or the like, by high frequency current or ultrasonic vibration. However, the surgical tools 117 depicted are mere examples at all, and as the surgical tools 117, various surgical tools which are generally used in endoscopic surgery such as, for example, a pair of tweezers or a retractor may be used.

An image of a surgical region in a body lumen of the patient 171 picked up by the endoscope 101 is displayed on a display apparatus 141. The surgeon 167 would use the energy treatment tool 121 or the forceps 123 while watching the image of the surgical region displayed on the display apparatus 141 on the real time basis to perform such treatment as, for example, resection of an affected area. It is to be noted that, though not depicted, the pneumoperitoneum tube 119, the energy treatment tool 121 and the forceps 123 are supported by the surgeon 167, an assistant, or the like, during surgery.

### <1-1. Supporting Arm Apparatus>

The supporting arm apparatus 127 includes an arm unit 131 extending from a base unit 129. In the example depicted, the arm unit 131 includes joint portions 133a, 133b and 133c and links 135a and 135b and is driven under the control of an arm controlling apparatus 145. The endoscope 101 is supported by the arm unit 131 such that the position and the posture of the endoscope 101 are controlled. Consequently, stable fixation in position of the endoscope 101 can be implemented.

### <1-2. Endoscope>

The endoscope 101 includes the lens barrel 103 which has a region of a predetermined length from a distal end thereof to be inserted into a body lumen of the patient 171, and a camera head 105 connected to a proximal end of the lens barrel 103. In the example depicted, the endoscope 101 is depicted which includes as a rigid endoscope having the lens barrel 103 of the hard type. However, the endoscope 101 may otherwise be configured as a flexible endoscope having the lens barrel 103 of the soft type.

The lens barrel 103 has, at a distal end thereof, an opening in which an objective lens is fitted. A light source apparatus 143 is connected to the endoscope 101 such that light generated by the light source apparatus 143 is introduced to a distal end of the lens barrel by a light guide extending in the inside of the lens barrel 103 and is irradiated toward an observation target in a body lumen of the patient 171 through the objective lens. It is to be noted that the endoscope 101 may be a front viewing endoscope or may be an oblique viewing endoscope or a side viewing endoscope.

An optical system and an image pickup element are provided in the inside of the camera head 105 such that reflected light (observation light) from an observation target is condensed on the image pickup element by the optical system. The observation light is photoelectrically converted by the image pickup element to generate an electric signal corresponding to the observation light, namely, an image signal corresponding to an observation image. The image signal is transmitted as RAW data to a CCU 139. It is to be noted that the camera head 105 has a function incorporated therein for suitably driving the optical system of the camera head 105 to adjust the magnification and the focal distance.

It is to be noted that, in order to establish compatibility with, for example, a stereoscopic vision (three dimensional (3D) display), a plurality of image pickup elements may be provided on the camera head 105. In this case, a plurality of relay optical systems are provided in the inside of the lens barrel 103 in order to guide observation light to each of the plurality of image pickup elements.

### <1-3. Various Apparatus Incorporated in Cart>

The CCU 139 is an example of the control apparatus according to the present disclosure. The CCU 139 includes a central processing unit (CPU), a graphics processing unit (GPU), or the like, and integrally controls operation of the endoscope 101 and the display apparatus 141. In particular, the CCU 139 performs, for an image signal received from the camera head 105, various image processes for displaying an image based on the image signal such as, for example, a development process (demosaic process). The CCU 139 provides the image signal for which the image processes have been performed to the display apparatus 141. Further, the CCU 139 transmits a control signal to the camera head 105 to control driving of the camera head 105. The control signal may include information relating to an image pickup condition such as a magnification or a focal distance.

The display apparatus 141 displays an image based on an image signal for which the image processes have been performed by the CCU 139 under the control of the CCU 139. If the endoscope 101 is ready for imaging of high resolution such as 4K (horizontal pixel number 3840×vertical pixel number 2160), 8K (horizontal pixel number 7680×vertical pixel number 4320), or the like, and/or ready for 3D display, then a display apparatus by which corresponding display of the high resolution and/or 3D display are possible may be used as the display apparatus 141. Where the apparatus is ready for imaging of high resolution such as 4K or 8K, if the display apparatus used as the display apparatus 141 has a size of equal to or not less than 55 inches, then a more immersive experience can be obtained. Further, a plurality of display apparatuses 141 having different types of resolution and/or different sizes may be provided in accordance with purposes.

The light source apparatus 143 is an example of the light source unit according to the present disclosure. The light source apparatus 143 includes a light emitting diode (LED), a laser light source, or the like, for example. The light source apparatus 143 supplies irradiation light for imaging of a surgical region to the endoscope 101.

The arm controlling apparatus 145 includes a processor such as, for example, a CPU and operates in accordance with a predetermined program to control driving of the arm unit 131 of the supporting arm apparatus 127 in accordance with a predetermined controlling method.

An inputting apparatus 147 is an input interface for the endoscopic surgery system 10. A user can perform inputting of various kinds of information or instruction inputting to the endoscopic surgery system 10 through the inputting apparatus 147. For example, the user would input various kinds of information relating to surgery such as physical information of a patient, information regarding a surgical procedure of the surgery and so forth through the inputting apparatus 147. Further, the user would input, for example, an instruction to drive the arm unit 131, an instruction to change an image pickup condition (type of irradiation light, magnification, focal distance or the like) by the endoscope 101, an instruction to drive the energy treatment tool 121, or the like, through the inputting apparatus 147.

The type of the inputting apparatus 147 is not limited and may be that of any one of various known inputting apparatus. As the inputting apparatus 147, for example, a mouse, a keyboard, a touch panel, a switch, a foot switch 157 and/or a lever, or the like, may be applied. Where a touch panel is used as the inputting apparatus 147, it may be provided on the display face of the display apparatus 141.

Otherwise, the inputting apparatus 147 is a device to be mounted on a user such as, for example, a glasses type wearable device or a head mounted display (HMD), and various kinds of inputting are performed in response to a gesture or a line of sight of the user detected by any of the devices mentioned. Further, the inputting apparatus 147 includes a camera which can detect a motion of a user, and various kinds of inputting are performed in response to a gesture or a line of sight of a user detected from a video picked up by the camera. Further, the inputting apparatus 147 includes a microphone which can collect the voice of a user, and various kinds of inputting are performed by voice collected by the microphone. By configuring the inputting apparatus 147 such that various kinds of information can be inputted in a contactless fashion in this manner, especially a user who belongs to a clean area (for example, the surgeon 167) can operate an apparatus belonging to an unclean area in a contactless fashion. Further, since the user can operate an apparatus without releasing a possessed surgical tool from its hand, the convenience to the user is improved.

A treatment tool controlling apparatus 149 controls driving of the energy treatment tool 121 for cautery or incision of a tissue, sealing of a blood vessel, or the like. A pneumoperitoneum apparatus 151 feeds gas into a body lumen of the patient 171 through the pneumoperitoneum tube 119 to inflate the body lumen in order to secure the field of view of the endoscope 101 and secure the working space for the surgeon. A recorder 153 is an apparatus capable of recording various kinds of information relating to surgery. A printer 155 is an apparatus capable of printing various kinds of information relating to surgery in various forms such as a text, an image or a graph.

In the following, especially a characteristic configuration of the endoscopic surgery system 10 is described in more detail.

### <1-4. Supporting Arm Apparatus>

The supporting arm apparatus 127 includes the base unit 129 serving as a base, and the arm unit 131 extending from the base unit 129. In the example depicted, the arm unit 131 includes the plurality of joint portions 133a, 133b and 133c and the plurality of links 135a and 135b connected to each other by the joint portion 133b. In FIG. 1, for simplified illustration, the configuration of the arm unit 131 is depicted in a simplified form. Actually, the shape, number and arrangement of the joint portions 133a to 133c and the links 135a and 135b and the direction and so forth of axes of rotation of the joint portions 133a to 133c can be set suitably such that the arm unit 131 has a desired degree of freedom. For example, the arm unit 131 may preferably be configured such that it has a degree of freedom equal to or not less than 6 degrees of freedom. This makes it possible to move the endoscope 101 freely within the movable range of the arm unit 131. Consequently, it becomes possible to insert the lens barrel 103 of the endoscope 101 from a desired direction into a body lumen of the patient 171.

An actuator is provided in each of the joint portions 133a to 133c, and the joint portions 133a to 133c are configured such that they are rotatable around predetermined axes of rotation thereof by driving of the respective actuators. The driving of the actuators is controlled by the arm controlling apparatus 145 to control the rotational angle of each of the joint portions 133a to 133c thereby to control driving of the arm unit 131. Consequently, control of the position and the posture of the endoscope 101 can be implemented. Thereupon, the arm controlling apparatus 145 can control driving of the arm unit 131 by various known controlling methods such as force control or position control.

For example, if the surgeon 167 suitably performs operation inputting through the inputting apparatus 147 (including the foot switch 157), then driving of the arm unit 131 may be controlled suitably by the arm controlling apparatus 145 in response to the operation input to control the position and the posture of the endoscope 101. After the endoscope 101 at the distal end of the arm unit 131 is moved from an arbitrary position to a different arbitrary position by the control just described, the endoscope 101 can be supported fixedly at the position after the movement. It is to be noted that the arm unit 131 may be operated in a master-slave fashion. In this case, the arm unit 131 may be remotely controlled by the user through the inputting apparatus 147 which is placed at a place remote from the surgery room.

Further, where force control is applied, the arm controlling apparatus 145 may perform power-assisted control to drive the actuators of the joint portions 133a to 133c such that the arm unit 131 may receive external force by the user and move smoothly following the external force. This makes it possible to move, when the user directly touches with and moves the arm unit 131, the arm unit 131 with comparatively weak force. Accordingly, it becomes possible for the user to move the endoscope 101 more intuitively by a simpler and easier operation, and the convenience to the user can be improved.

Here, generally in endoscopic surgery, the endoscope 101 is supported by a medical doctor called scopist. In contrast, where the supporting arm apparatus 127 is used, the position of the endoscope 101 can be fixed more certainly without hands, and therefore, an image of a surgical region can be obtained stably, and surgery can be performed smoothly.

It is to be noted that the arm controlling apparatus 145 may not necessarily be provided on the cart 137. Further, the arm controlling apparatus 145 may not necessarily be a single apparatus. For example, the arm controlling apparatus 145 may be provided in each of the joint portions 133a to 133c of the arm unit 131 of the supporting arm apparatus 127 such that the plurality of arm controlling apparatus 145 cooperate with each other to implement driving control of the arm unit 131.

### <1-5. Light Source Apparatus>

The light source apparatus 143 supplies irradiation light when the endoscope 101 is caused to image a surgical region. The light source apparatus 143 includes, for example, an LED, a laser light source or a white light source configured by combination of these.

Further, driving of the light source apparatus 143 may be controlled such that the intensity of light to be outputted is changed for each predetermined time. By controlling driving of the image pickup element of the camera head 105 in synchronism with the timing of the change of the intensity of light to acquire images time-divisionally and synthesizing the images, an image of a high dynamic range free from underexposed blocked up shadows and overexposed highlights can be created.

Further, the light source apparatus 143 is configured to supply light (visible light and infrared light) of a predetermined wavelength band ready for special light observation. In special light observation, for example, by utilizing the wavelength dependency of absorption of light in a body tissue to radiate light of a narrower band in comparison with irradiation light upon ordinary observation (namely, white light), narrow band light observation (narrow band imaging) of imaging a predetermined tissue such as a blood vessel of a superficial portion of the mucous membrane, or the like, in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by radiating excitation light on the body tissue (autofluorescence observation) or to obtain a fluorescent light image by locally injecting a reagent such as indocyanine green (ICG) into a body tissue and radiating excitation light corresponding to a fluorescent light wavelength of the reagent upon the body tissue. The light source apparatus 143 can be configured to supply such narrow-band light and/or excitation light suitable for special light observation as described above.

### <1-6. Camera Head>

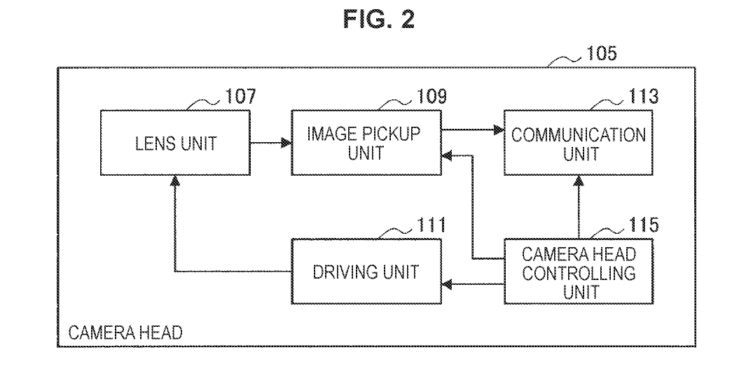

Functions of the camera head 105 of the endoscope 101 are described in more detail with reference to FIG. 2. FIG. 2 is a block diagram depicting an example of a functional configuration of the camera head 105 depicted in FIG. 1.

Referring to FIG. 2, the camera head 105 has, as functions thereof, a lens unit 107, an image pickup unit 109, a driving unit 111, a communication unit 113 and a camera head controlling unit 115. Note that the camera head 105 and the CCU 139 are connected to be bidirectionally communicable to each other by a transmission cable (not depicted).

The lens unit 107 is an optical system provided at a connecting location of the camera head 105 to the lens barrel 103. Observation light taken in from a distal end of the lens barrel 103 is introduced into the camera head 105 and enters the lens unit 107. The lens unit 107 includes a combination of a plurality of lenses including a zoom lens and a focusing lens. The lens unit 107 has optical properties adjusted such that the observation light is condensed on a light receiving face of the image pickup element of the image pickup unit 109. Further, the zoom lens and the focusing lens are configured such that the positions thereof on their optical axis are movable for adjustment of the magnification and the focal point of a picked up image.

The image pickup unit 109 includes an image pickup element and disposed at a succeeding stage to the lens unit 107. Observation light having passed through the lens unit 107 is condensed on the light receiving face of the image pickup element, and an image signal corresponding to the observation image is generated by photoelectric conversion of the image pickup element. The image signal generated by the image pickup unit 109 is provided to the communication unit 113.

As the image pickup element which is included by the image pickup unit 109 is an image sensor including a rolling shutter mechanism such as the complementary metal oxide semiconductor (CMOS), for example, and which has a Bayer array and is capable of picking up an image in color is used. It is to be noted that, as the image pickup element, an image pickup element may be used which is ready, for example, for imaging of an image of high resolution equal to or not less than 4K. If an image of a surgical region is obtained in high resolution, then the surgeon 167 can comprehend a state of the surgical region in enhanced details and can proceed with the surgery more smoothly.

Further, the image pickup element which is included by the image pickup unit 109 includes such that it has a pair of image pickup elements for acquiring image signals for the right eye and the left eye compatible with 3D display. Where 3D display is applied, the surgeon 167 can comprehend the depth of a living body tissue in the surgical region more accurately. It is to be noted that, if the image pickup unit 109 is configured as that of the multi-plate type, then a plurality of systems of lens units 107 are provided corresponding to the individual image pickup elements of the image pickup unit 109.

The image pickup unit 109 may not necessarily be provided on the camera head 105. For example, the image pickup unit 109 may be provided just behind the objective lens in the inside of the lens barrel 103.

The driving unit 111 includes an actuator and moves the zoom lens and the focusing lens of the lens unit 107 by a predetermined distance along the optical axis under the control of the camera head controlling unit 115. Consequently, the magnification and the focal point of a picked up image by the image pickup unit 109 can be adjusted suitably.

The communication unit 113 includes a communication apparatus for transmitting and receiving various kinds of information to and from the CCU 139. The communication unit 113 transmits an image signal acquired from the image pickup unit 109 as RAW data to the CCU 139. Thereupon, in order to display a picked up image of a surgical region in low latency, the image signal is preferably transmitted by optical communication. This is because, upon surgery, the surgeon 167 performs surgery while observing the state of an affected area through a picked up image, it is demanded for a moving image of the surgical region to be displayed on the real time basis as far as possible in order to achieve surgery with a higher degree of safety and certainty. Where optical communication is applied, a photoelectric conversion module for converting an electric signal into an optical signal is provided in the communication unit 113. After the image signal is converted into an optical signal by the photoelectric conversion module, it is transmitted to the CCU 139 through the transmission cable.

Further, the communication unit 113 receives a control signal for controlling driving of the camera head 105 from the CCU 139. The control signal includes information relating to image pickup conditions such as, for example, information that a frame rate of a picked up image is designated, information that an exposure value upon image picking up is designated and/or information that a magnification and a focal point of a picked up image are designated. The communication unit 113 provides the received control signal to the camera head controlling unit 115. It is to be noted that also the control signal from the CCU 139 may be transmitted by optical communication. In this case, a photoelectric conversion module for converting an optical signal into an electric signal is provided in the communication unit 113. After the control signal is converted into an electric signal by the photoelectric conversion module, it is provided to the camera head controlling unit 115.

It is to be noted that the image pickup conditions such as the frame rate, exposure value, magnification or focal point are set automatically by the CCU 139 on the basis of an acquired image signal. In other words, an auto exposure (AE) function, an auto focus (AF) function and an auto white balance (AWB) function are incorporated in the endoscope 101.

The camera head controlling unit 115 controls driving of the camera head 105 on the basis of a control signal from the CCU 139 received through the communication unit 113. For example, the camera head controlling unit 115 controls driving of the image pickup element of the image pickup unit 109 on the basis of information that a frame rate of a picked up image is designated and/or information that an exposure value upon image picking up is designated. Further, for example, the camera head controlling unit 115 controls the driving unit 111 to suitably move the zoom lens and the focus lens of the lens unit 107 on the basis of information that a magnification and a focal point of a picked up image are designated. The camera head controlling unit 115 may further include a function for storing information for identifying the lens barrel 103 and/or the camera head 105.

It is to be noted that, by disposing the components such as the lens unit 107 and the image pickup unit 109 in a sealed structure having high airtightness and waterproof, the camera head 105 can be provided with resistance to an autoclave sterilization process.

### <1-7. Organization of Problems>

The configuration of the control system according to a first embodiment has been described above. By the way, in these days, for example, a technology of performing imaging while frame-sequentially radiating special light and white light for the purpose of ICG angiography, 5-ALA PDD fluorescent observation, or the like, and displaying the image picked up with special light and the image picked up with white light in a superimposed manner has been proposed. According to this display in a superimposed manner, it is possible to improve visibility of a region of interest such as blood vessels and an involved area and improve visibility of a region other than the region of interest which is difficult to be seen only through image pickup with special light. As a result, it is possible to make a surgical technology more efficient.

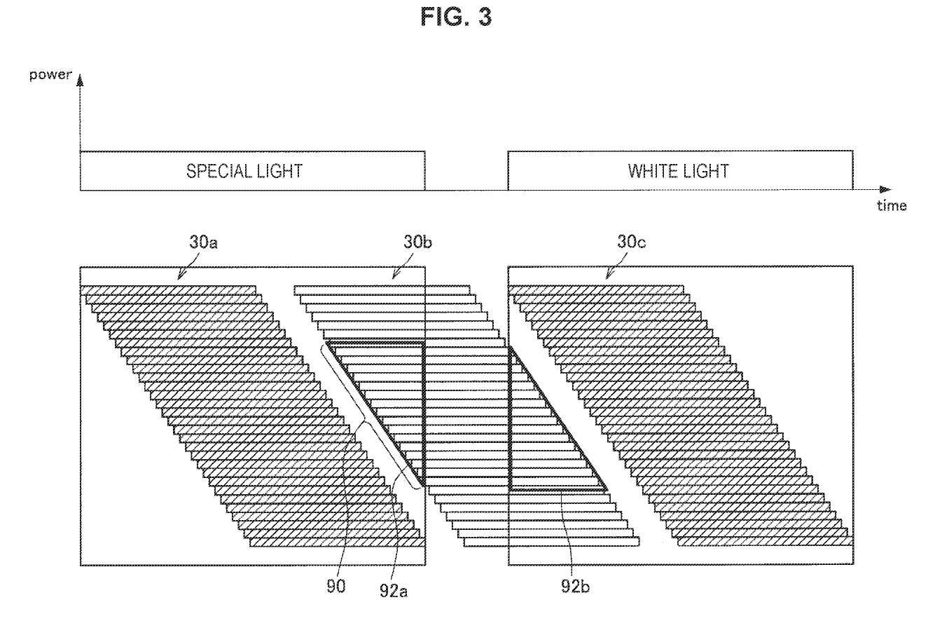

However, with a publicly known technology, if frame sequential imaging is performed using an image pickup element having a rolling shutter mechanism, there is a problem that a frame in which two colors of special light and white light are mixed occurs. FIG. 3 is an explanatory diagram illustrating this problem. FIG. 3 illustrates temporal relationship between an exposure timing of the image pickup element and periods while the special light and the white light are respectively radiated for each frame 30 with the publicly known technology. As in a frame 30b illustrated in FIG. 3, with the publicly known technology, a frame in which two colors of special light and white light are mixed occurs in part of lines 90 in the image pickup element. More specifically, in a frame 30b, in part of lines 90, special light is radiated during an exposure period 92a and white light is radiated during an exposure period 92b. Then, because such a color mixture frame is normally not used and is discarded, a presentation frame rate is lowered.

Therefore, in view of the above-described circumstances, the CCU 139 according to the present embodiment has been created. In the present embodiment, only lines from the top line to the bottom line among all the lines included in the image pickup element of the image pickup unit 109 are dealt as an image pickup range. Then, the CCU 139 determines a period in accordance with a period between an exposure start timing of the bottom line in the image pickup element and an exposure end timing of the top line in the image pickup element as an irradiation period during which the light source apparatus 143 is caused to radiate light. By this means, in a scene in which frame sequential imaging is performed, it is possible to prevent occurrence of a color mixture frame. Note that the top line is an example of a second line in the present disclosure, and the bottom line is an example of a first line in the present disclosure. Further, the top line is a line in which start of exposure is earlier than in the bottom line in each frame.

### 2. DETAILED DESCRIPTION OF EMBODIMENT

### 2-1. Configuration>

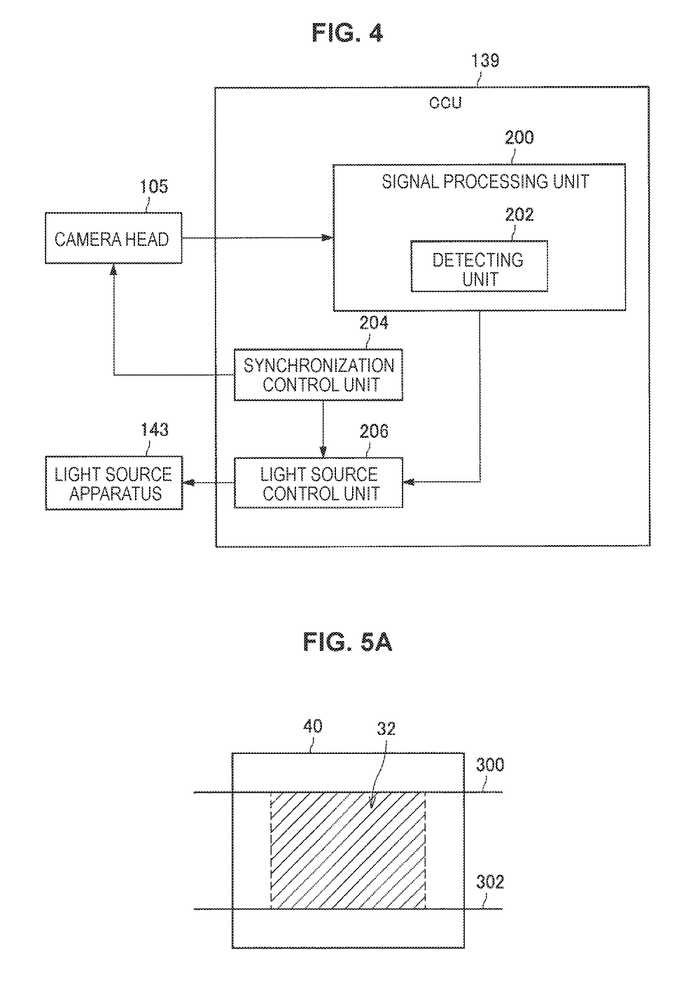

A configuration of the CCU 139 according to the present embodiment will be described in detail next. FIG. 4 is a functional block diagram illustrating a configuration example of the CCU 139 according to the present embodiment. As illustrated in FIG. 4, the CCU 139 includes a signal processing unit 200, a synchronization control unit 204 and a light source control unit 206. Further, the signal processing unit 200 includes a detecting unit 202.

### {2-1-1. Detecting Unit 202}

### (2-1-1-1. Determination of Line)

The detecting unit 202 is an example of a line determining unit in the present disclosure. The detecting unit 202 determines the top line and the bottom line in the image pickup element of the image pickup unit 109 on the basis of predetermined criteria.

For example, the predetermined criteria can include zoom information (such as zoom magnification) designated by the user. In this case, the detecting unit 202 determines line numbers of the respective top line and bottom line on the basis of the designated zoom information. For example, in the case where the zoom magnification is increased, the detecting unit 202 determines the respective line numbers so that an interval between the top line and the bottom line becomes narrower. Alternatively, the detecting unit 202 may specify a display region in the image pickup element on the basis of the designated zoom information and may determine the top line and the bottom line on the basis of the specified display region.

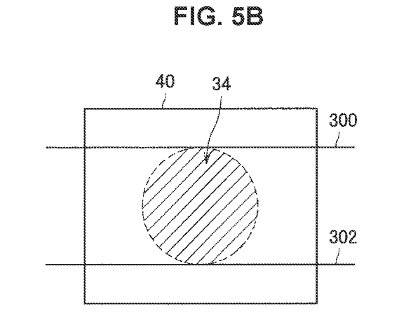

FIG. 5A is an explanatory diagram illustrating an example of determination of the top line and the bottom line based on the display region 32 specified in the image pickup element 40. As illustrated in FIG. 5A, for example, the detecting unit 202 determines an upper end of the display region 32 (or a line above the upper end by predetermined lines) as the top line 300 and determines a lower end of the display region 32 (or a line below the lower end by predetermined lines) as the bottom line 302.

Alternatively, the predetermined criteria can include scope information of the endoscope 101. Here, the scope information can include, for example, information of an ID of the lens barrel 103, a size of a radius of the lens barrel 103 and/or a shape of the lens barrel 103, or the like. For example, the detecting unit 202 determines the respective line numbers so that the interval between the top line and the bottom line becomes greater as the radius of the lens barrel 103 is greater.

Alternatively, the predetermined criteria can include information of a mask region in an image picked up by the image pickup unit 109. Here, the mask region is a region (region corresponding to a protruding range) around an effective region in the image picked up by the image pickup unit 109. For example, in the case where the picked up image is an image of a surgical region inside a body cavity of the patient 171, the mask region is a region which does not appear in an intravital video, such as a left end, a right end, an upper end or a lower end in the image. For example, the detecting unit 202 determines the top line and the bottom line on the basis of a boundary between the mask region and the effective region.

FIG. 5B is an explanatory diagram illustrating an example of determination of the top line and the bottom line based on mask region information. For example, the detecting unit 202 first specifies the effective region 34 in the image pickup element 40 on the basis of the mask region information. Then, the detecting unit 202 determines an upper limit of the specified effective region 34 as the top line 300 and determines a lower limit of the effective region 34 as the bottom line 302.

Note that the mask region information may be specified by applying a predetermined image process technology to the image picked up by the image pickup unit 109 or may be specified on the basis of the scope information of the endoscope 101. In the latter case, for example, the detecting unit 202 may specify the mask region information by specifying the radius of the lens barrel 103 corresponding to a scope ID of the endoscope 101 or may specify the mask region information using a table in which the mask region information is registered in association with the scope information.

Note that the detecting unit 202 may determine the top line and the bottom line on the basis of only one of the above-described predetermined criteria or may determine the top line and the bottom line on the basis of any two or more among the above-described predetermined criteria.

### (2-1-1-2. Change of Lines)

Further, the detecting unit 202 can change the top line and the bottom line on the basis of change of values indicated by the above-described predetermined criteria. For example, in the case where it is determined that the zoom magnification is changed, the detecting unit 202 changes the top line and the bottom line on the basis of the changed zoom magnification. Note that the detecting unit 202 can monitor whether or not the values indicated by the above-described predetermined criteria change for each frame.

### (2-1-1-.3. Detection Process)

Further, the detecting unit 202 can perform a detection process on an image signal for performing AE, AF and AWB.

### {2-1-2. Synchronization Control Unit 204}

The synchronization control unit 204 performs control for synchronizing a timing between the camera head 105 and the light source apparatus 143. For example, the synchronization control unit 204 provides a synchronization signal to the camera head 105 and the light source control unit 206. This synchronization signal can be a signal indicating an exposure start timing of a head line in the image pickup element in the corresponding frame.

### {2-1-3. Light Source Control Unit 206}

### (2-1-3-1. Determination of Irradiation Period)

The light source control unit 206 determines the irradiation period during which the light source apparatus 143 is caused to radiate light on the basis of the synchronization signal provided from the synchronization control unit 204 and the top line and the bottom line determined by the detecting unit 202. More specifically, the light source control unit 206 determines a period in accordance with a period between the exposure start timing of the bottom line and the exposure end timing of the top line as the irradiation period. Here, the exposure end timing of the top line is a timing at which a length of the exposure period of the top line has elapsed since the exposure start timing of the top line.

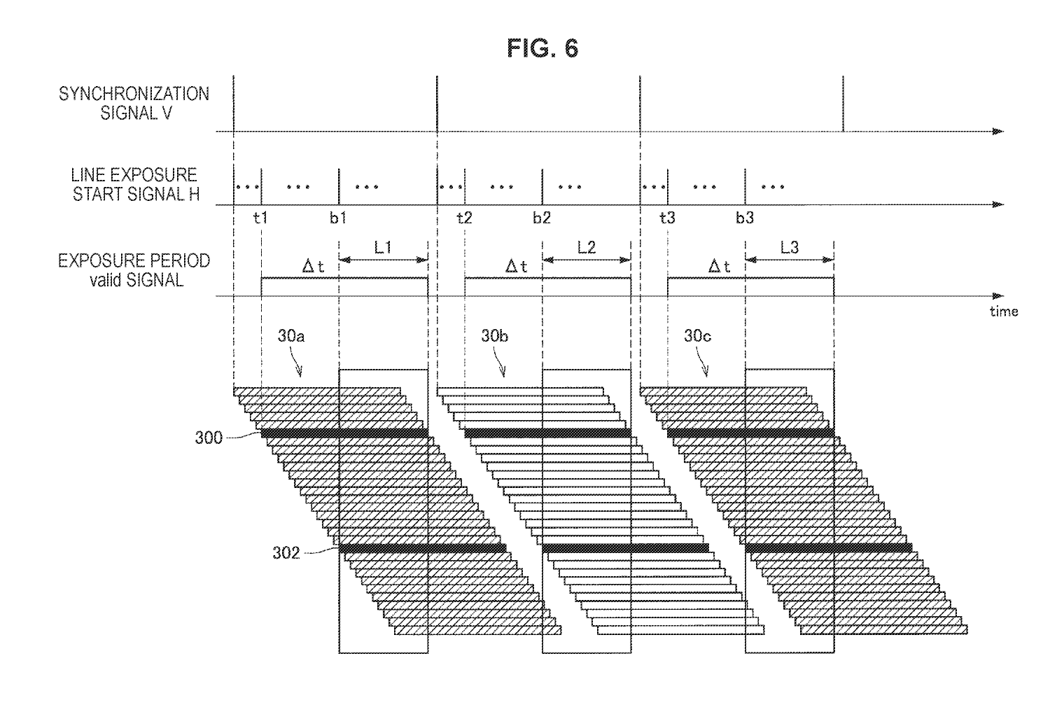

FIG. 6 is an explanatory diagram illustrating an example of determination of the irradiation period L. Note that the synchronization signal V illustrated in FIG. 6 can be provided for each frame by the synchronization control unit 204 as mentioned above. Further, a line exposure start signal H is a signal which gives an instruction of start of exposure of each line. As illustrated in FIG. 6, the line exposure start signal H can be sequentially output for each line while being delayed by a predetermined time period from the synchronization signal V of the corresponding frame. Note that, in the example illustrated in FIG. 6, concerning the frame 30a, an output timing of the exposure start signal of the top line 300 is indicated as t1 and an output timing of the exposure start signal of the bottom line 302 is indicated as b1. Further, an exposure period valid signal is a signal which specifies a length (=Δt) of an exposure period of each line. Note that the exposure period valid signal can be automatically set on the basis of frame rate setting information of the image pickup unit 109, for example, in the case where a frame rate is 60 Hz, Δt is set at approximately 16.66 seconds.

In the example illustrated in FIG. 6, the light source control unit 206 calculates an irradiation period L1 on the basis of the exposure start timing (=t1) of the top line, the exposure start timing (=b1) of the bottom line and the length of the exposure period (=Δt) as indicated with the following equation (1).

[Math. 1]

L1=t1+Δt−b1 equation (1)

Note that, unless the top line and the bottom line are changed, the light source control unit 206 can determine the length of the irradiation period of each frame at the same length as the length of the irradiation period which is initially calculated. Further, in the case where the top line or the bottom line is changed by the detecting unit 202, the light source control unit 206 calculates the irradiation period again on the basis of the changed top line and the changed bottom line.

### (2-1-3-2. Control Example 1)

Further, the light source control unit 206 causes the light source apparatus 143 to radiate light for only the determined length of the irradiation period from the exposure start timing of the bottom line for each frame. Further, the light source control unit 206 does not cause the light source apparatus 143 to radiate light during a period other than the irradiation period. For example, the light source control unit 206 transmits an irradiation start signal which gives an instruction of starting irradiation of light at the exposure start timing of the bottom line to the light source apparatus 143 for each frame, and transmits an irradiation end signal which gives an instruction of finishing irradiation of light at the exposure end timing of the top line to the light source apparatus 143. According to this control example, because the same light amount is radiated in each line within the image pickup range (that is, lines from the top line to the bottom line), it is possible to prevent a light receiving amount from being different for each line.

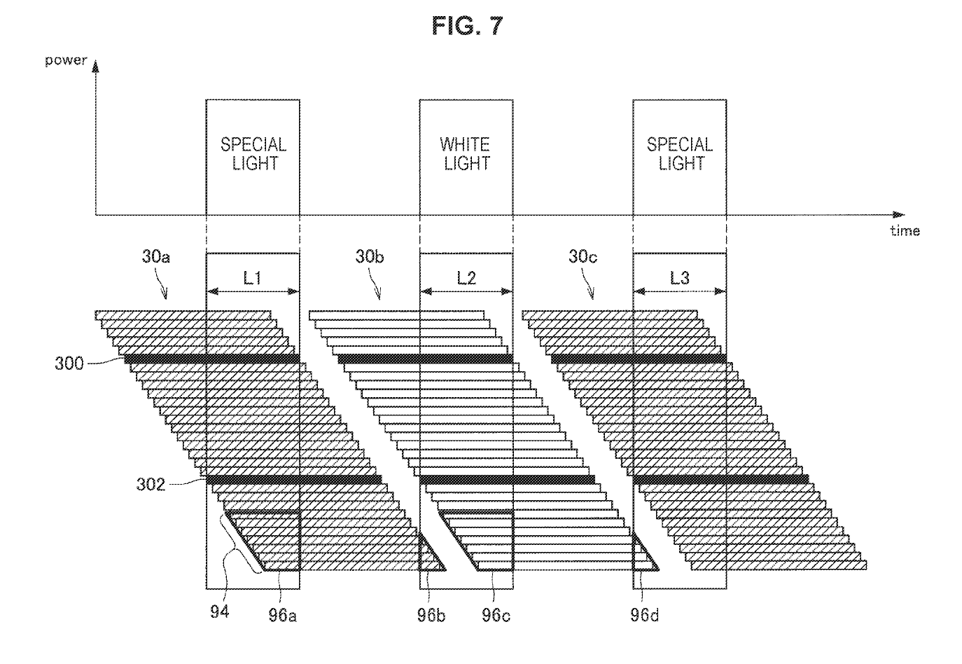

FIG. 7 is an explanatory diagram illustrating a control example of irradiation of light by the light source control unit 206. As illustrated in FIG. 7, for example, the light source control unit 206 causes the light source apparatus 143 to alternately radiate white light and special light for each frame. That is, the light source control unit 206 causes the light source apparatus 143 to perform frame sequential irradiation. Further, as illustrated in FIG. 7, the light source control unit 206 sets a shorter irradiation period for each irradiation than that in the publicly known technology as illustrated in, for example, FIG. 3, and causes the light source apparatus 143 to radiate white light and special light at higher intensity. By this means, it is possible to secure a sufficient exposure amount and prevent white light and special light from being mixed in the image pickup range.

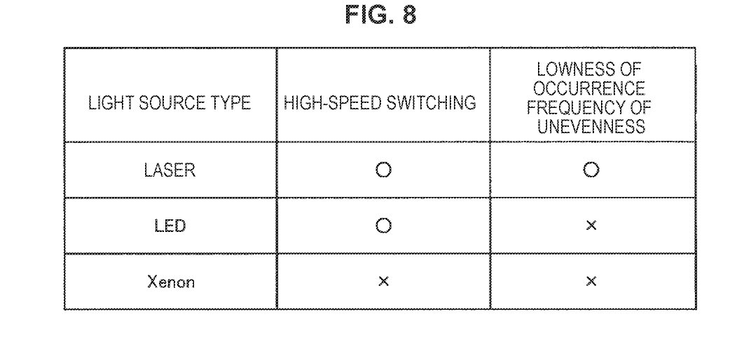

Note that, to realize such irradiation control, the light source apparatus 143 needs to be a light source of a type which can switch types of irradiation light at high speed such as, for example, on the order of several milliseconds. Therefore, as illustrated in FIG. 8, it is necessary to use, for example, a laser light source or an LED instead of a xenon light source as the light source apparatus 143. Then, the light source apparatus 143 is preferably a laser light source. In this case, as illustrated in FIG. 8, the light source apparatus 143 can irradiate an observation target with even light even if the irradiation period is short.

Note that, in the example illustrated in FIG. 7, in the frame 30a, part of lines 94 outside the image pickup range is irradiated with special light during an exposure period 96a, and is irradiated with white light during an exposure period 96b. However, because the lines 94 are outside the image pickup range, data picked up in the lines 94 is discarded through a signal process at a succeeding stage (for example, by the signal processing unit 200). Therefore, the data does not affect image quality of the obtained image. Alternatively, the camera head 105 can also output only data imaged in the image pickup range to a signal process at a succeeding stage.

### (2-1-3-3. Control Example 2)

As a modified example, the light source control unit 206 can also cause the light source apparatus 143 to radiate only white light in each frame (instead of performing frame sequential irradiation). According to this control example, the following two effects can be obtained. First, because white light is continuously radiated on an observation target, effects similar to effects obtained from stroboscopic imaging can be obtained. Note that, while it is desired to minimize the irradiation period because a risk of a burn is concerned in medical care, according to the present modified example, because white light is radiated on limited lines, it is possible to shorten an irradiation period, so that it is possible to obtain an effect of being capable of avoiding a risk of a burn. Secondly, it is possible to pick up a sharper image with less motion blur (compared to a case where no white light is radiated).

### {2-1-4. Signal Processing Unit 200}

The signal processing unit 200 performs various image processes on image signals transmitted from the camera head 105 on the basis of the top line and the bottom line determined by the detecting unit 202. For example, the signal processing unit 200 first determines a range between the top line and the bottom line in the image pickup element as an image process range. Then, the signal processing unit 200 extracts only image signals corresponding to the determined image process range among the image signals transmitted from the camera head 105, and performs various image processes on the extracted image signals. The image processes include various kinds of publicly known signal processes such as, for example, a development process and an image quality improving process (such as a bandwidth enhancement process, a super-resolution process, a noise reduction (NR) process and/or a camera shake correction process).

Further, the signal processing unit 200 can perform a process of superimposing an image picked up with special light and an image picked up with white light. By this means, it is possible to cause an image obtained by superimposing the image picked up with special light and the image picked up with white light to be displayed at the display apparatus 141.

### <2-2. Operation>

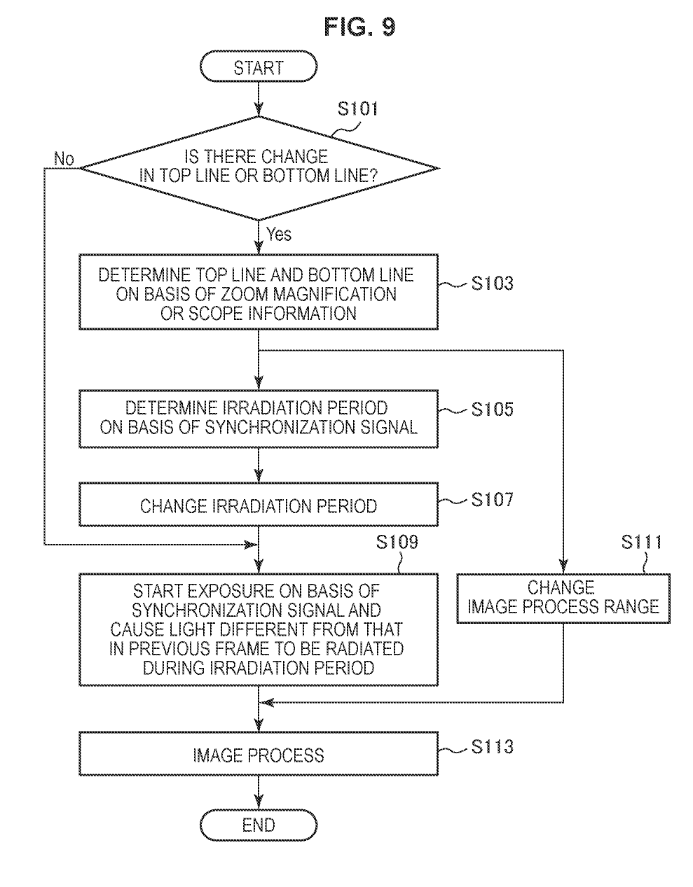

The configuration according to the present embodiment has been described above. Operation according to the present embodiment will be described next with reference to FIG. 9. FIG. 9 is a flowchart illustrating an operation example according to the present embodiment. Note that the operation illustrated in FIG. 9 is executed for each frame.

As illustrated in FIG. 9, first, the detecting unit 202 of the CCU 139 monitors whether or not the top line or the bottom line in the image pickup element of the image pickup unit 109 should be changed on the basis of change of values of the predetermined criteria (S101). In the case where it is determined that neither the top line nor the bottom line should be changed (S101: No), the CCU 139 performs a process in S109 which will be described later.

Meanwhile, in the case where it is determined that the top line or the bottom line should be changed, or the top line and the bottom line are not yet set (S101: Yes), the detecting unit 202 changes the top line and the bottom line on the basis of the predetermined criteria (such as, for example, zoom magnification and scope information) (S103).

Subsequently, the synchronization control unit 204 provides a synchronization signal to the camera head 105 and the light source control unit 206. The light source control unit 206 then specifies an exposure start timing of the top line and an exposure start timing of the bottom line, which are changed in S103, on the basis of the provided synchronization signal. The light source control unit 206 then determines an irradiation period (S105) on the basis of the exposure start timing of the top line, the exposure start timing of the bottom line and a length of an exposure period (of each line) and, then, changes the irradiation period to the determined period (S107).

Subsequently, the image pickup unit 109 of the camera head 105 starts exposure on the basis of the provided synchronization signal. Further, the light source control unit 206 causes the light source apparatus 143 to radiate light (white light or special light) different from that in the previous frame on the basis of the provided synchronization signal. Thereafter, the camera head 105 transmits image signals obtained by the image pickup unit 109 to the CCU 139 (S109).

Further, after S103, the signal processing unit 200 changes a current image process range to a range from the top line and the bottom line changed in S103 (S111).

After S109 and S111, the signal processing unit 200 extracts image signals corresponding to the image process range set in S111 among the image signals received in S109 and, then, performs various image processes on the extracted image signals (S113).

### <2-3. Effects>

As described above, according to the present embodiment, the CCU 139 determines a period in accordance with a period between the exposure start timing of the bottom line in the image pickup element of the image pickup unit 109 and the exposure end timing of the top line in the image pickup element as an irradiation period during which the light source apparatus 143 is caused to radiate light. Therefore, it is possible to determine an appropriate irradiation period in a scene in which light is radiated upon imaging using an image pickup element having a rolling shutter mechanism.

Further, the CCU 139 causes the light source apparatus 143 to alternately radiate white light and special light for each frame and causes the light source apparatus 143 to radiate light only in the irradiation period for each frame. By this means, it is possible to prevent occurrence of a color mixture frame, so that it is possible to prevent lowering of a frame rate.

Further, the light source apparatus 143 can include a laser light source. Therefore, it is possible to switch types of irradiation light at high speed and irradiate an observation target with even light even if the irradiation period is short. It is, for example, possible to prevent variation of an exposure amount among frames.

### 3. APPLICATION EXAMPLES

Note that the technology according to the present disclosure can be applied to various products. For example, the technology according to the present disclosure may be applied to a microscopic surgery system used in so-called microsurgery which is performed while a minute region of a patient is enlarged and observed.

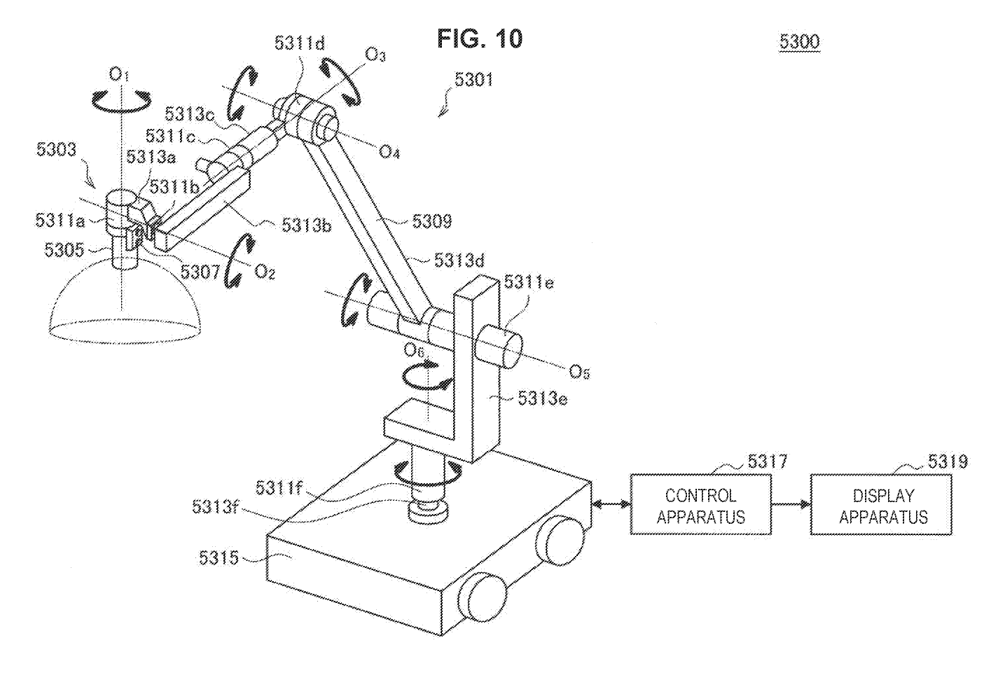

FIG. 10 is a view depicting an example of a schematic configuration of a microscopic surgery system 5300 to which the technology according to an embodiment of the present disclosure can be applied. Referring to FIG. 10, the microscopic surgery system 5300 includes a microscope apparatus 5301, a control apparatus 5317 and a display apparatus 5319. It is to be noted that, in the description of the microscopic surgery system 5300, the term “user” signifies an arbitrary one of medical staff members such as a surgery or an assistant who uses the microscopic surgery system 5300.

The microscope apparatus 5301 has a microscope unit 5303 for enlarging an observation target (surgical region of a patient) for observation, an arm unit 5309 which supports the microscope unit 5303 at a distal end thereof, and a base unit 5315 which supports a proximal end of the arm unit 5309.

The microscope unit 5303 includes a cylindrical portion 5305 of a substantially cylindrical shape, an image pickup unit (not depicted) provided in the inside of the cylindrical portion 5305, and an operation unit 5307 provided in a partial region of an outer circumference of the cylindrical portion 5305. The microscope unit 5303 is a microscope unit of the electronic image pickup type (microscope unit of the video type) which picks up an image electronically by the image pickup unit.

A cover glass member for protecting the internal image pickup unit is provided at an opening face of a lower end of the cylindrical portion 5305. Light from an observation target (hereinafter referred to also as observation light) passes through the cover glass member and enters the image pickup unit in the inside of the cylindrical portion 5305. It is to be noted that a light source includes, for example, a light emitting diode (LED) or the like may be provided in the inside of the cylindrical portion 5305, and upon image picking up, light may be irradiated upon an observation target from the light source through the cover glass member.

The image pickup unit includes an optical system which condenses observation light, and an image pickup element which receives the observation light condensed by the optical system. The optical system includes a combination of a plurality of lenses including a zoom lens and a focusing lens. The optical system has optical properties adjusted such that the observation light is condensed to be formed image on a light receiving face of the image pickup element. The image pickup element receives and photoelectrically converts the observation light to generate a signal corresponding to the observation light, namely, an image signal corresponding to an observation image. As the image pickup element, for example, an image pickup element which has a Bayer array and is capable of picking up an image in color is used. The image pickup element may be any of various known image pickup elements such as a complementary metal oxide semiconductor (CMOS) image sensor or a charge coupled device (CCD) image sensor. The image signal generated by the image pickup element is transmitted as RAW data to the control apparatus 5317. Here, the transmission of the image signal may be performed suitably by optical communication. This is because, since, at a surgery site, the surgeon performs surgery while observing the state of an affected area through a picked up image, in order to achieve surgery with a higher degree of safety and certainty, it is demanded for a moving image of the surgical region to be displayed on the real time basis as far as possible. Where optical communication is used to transmit the image signal, the picked up image can be displayed with low latency.

It is to be noted that the image pickup unit may have a driving mechanism for moving the zoom lens and the focusing lens of the optical system thereof along the optical axis. Where the zoom lens and the focusing lens are moved suitably by the driving mechanism, the magnification of the picked up image and the focal distance upon image picking up can be adjusted. Further, the image pickup unit may incorporate therein various functions which may be provided generally in a microscopic unit of the electronic image pickup such as an auto exposure (AE) function or an auto focus (AF) function.

Further the image pickup unit may be configured as an image pickup unit of the single-plate type which includes a single image pickup element or may be configured as an image pickup unit of the multi-plate type which includes a plurality of image pickup elements. Where the image pickup unit is configured as that of the multi-plate type, for example, image signals corresponding to red, green, and blue colors may be generated by the image pickup elements and may be synthesized to obtain a color image. Alternatively, the image pickup unit may be configured such that it has a pair of image pickup elements for acquiring image signals for the right eye and the left eye compatible with a stereoscopic vision (three dimensional (3D) display). Where 3D display is applied, the surgeon can comprehend the depth of a living body tissue in the surgical region with a higher degree of accuracy. It is to be noted that, if the image pickup unit is configured as that of stereoscopic type, then a plurality of optical systems are provided corresponding to the individual image pickup elements.

The operation unit 5307 includes, for example, a cross lever, a switch or the like and accepts an operation input of the user. For example, the user can input an instruction to change the magnification of the observation image and the focal distance to the observation target through the operation unit 5307. The magnification and the focal distance can be adjusted by the driving mechanism of the image pickup unit suitably moving the zoom lens and the focusing lens in accordance with the instruction. Further, for example, the user can input an instruction to switch the operation mode of the arm unit 5309 (an all-free mode and a fixed mode hereinafter described) through the operation unit 5307. It is to be noted that when the user intends to move the microscope unit 5303, it is supposed that the user moves the microscope unit 5303 in a state in which the user grasps the microscope unit 5303 holding the cylindrical portion 5305. Accordingly, the operation unit 5307 is preferably provided at a position at which it can be operated readily by the fingers of the user with the cylindrical portion 5305 held such that the operation unit 5307 can be operated even while the user is moving the cylindrical portion 5305.

The arm unit 5309 is configured such that a plurality of links (first link 5313a to sixth link 5313f) are connected for rotation relative to each other by a plurality of joint portions (first joint portion 5311a to sixth joint portion 5311f).

The first joint portion 5311a has a substantially columnar shape and supports, at a distal end (lower end) thereof, an upper end of the cylindrical portion 5305 of the microscope unit 5303 for rotation around an axis of rotation (first axis O₁) parallel to the center axis of the cylindrical portion 5305. Here, the first joint portion 5311a may be configured such that the first axis O₁ thereof is in alignment with the optical axis of the image pickup unit of the microscope unit 5303. By the configuration, if the microscope unit 5303 is rotated around the first axis O₁, then the field of view can be changed so as to rotate the picked up image.

The first link 5313a fixedly supports, at a distal end thereof, the first joint portion 5311a. Specifically, the first link 5313a is a bar-like member having a substantially L shape and is connected to the first joint portion 5311a such that one side at the distal end side thereof extends in a direction orthogonal to the first axis O₁ and an end portion of the one side abuts with an upper end portion of an outer periphery of the first joint portion 5311a. The second joint portion 5311b is connected to an end portion of the other side on the proximal end side of the substantially L shape of the first link 5313a.

The second joint portion 5311b has a substantially columnar shape and supports, at a distal end thereof, a proximal end of the first link 5313a for rotation around an axis of rotation (second axis O₂) orthogonal to the first axis O₁. The second link 5313b is fixedly connected at a distal end thereof to a proximal end of the second joint portion 5311b.

The second link 5313b is a bar-like member having a substantially L shape, and one side of a distal end side of the second link 5313b extends in a direction orthogonal to the second axis O₂ and an end portion of the one side is fixedly connected to a proximal end of the second joint portion 5311b. The third joint portion 5311c is connected to the other side at the proximal end side of the substantially L shape of the second link 5313b.

The third joint portion 5311c has a substantially columnar shape and supports, at a distal end thereof, a proximal end of the second link 5313b for rotation around an axis of rotation (third axis O₃) orthogonal to the first axis O₁ and the second axis O₂. The third link 5313c is fixedly connected at a distal end thereof to a proximal end of the third joint portion 5311c. By rotating the components at the distal end side including the microscope unit 5303 around the second axis O₂ and the third axis O₃, the microscope unit 5303 can be moved such that the position of the microscope unit 5303 is changed within a horizontal plane. In other words, by controlling the rotation around the second axis O₂ and the third axis O₃, the field of view of the picked up image can be moved within a plane.

The third link 5313c is configured such that the distal end side thereof has a substantially columnar shape, and a proximal end of the third joint portion 5311c is fixedly connected to the distal end of the columnar shape such that both of them have a substantially same center axis. The proximal end side of the third link 5313c has a prismatic shape, and the fourth joint portion 5311d is connected to an end portion of the third link 5313c.

The fourth joint portion 5311d has a substantially columnar shape and supports, at a distal end thereof, a proximal end of the third link 5313c for rotation around an axis of rotation (fourth axis O₄) orthogonal to the third axis O₃. The fourth link 5313d is fixedly connected at a distal end thereof to a proximal end of the fourth joint portion 5311d.

The fourth link 5313d is a bar-like member extending substantially linearly and is fixedly connected to the fourth joint portion 5311d such that it extends orthogonally to the fourth axis O₄ and abuts at an end portion of the distal end thereof with a side face of the substantially columnar shape of the fourth joint portion 5311d. The fifth joint portion 5311e is connected to a proximal end of the fourth link 5313d.

The fifth joint portion 5311e has a substantially columnar shape and supports, at a distal end side thereof, a proximal end of the fourth link 5313d for rotation around an axis of rotation (fifth axis O₅) parallel to the fourth axis O₄. The fifth link 5313e is fixedly connected at a distal end thereof to a proximal end of the fifth joint portion 5311e. The fourth axis O₄ and the fifth axis O₅ are axes of rotation around which the microscope unit 5303 can be moved in the upward and downward direction. By rotating the components at the distal end side including the microscope unit 5303 around the fourth axis O₄ and the fifth axis O₅, the height of the microscope unit 5303, namely, the distance between the microscope unit 5303 and an observation target, can be adjusted.

The fifth link 5313e includes a combination of a first member having a substantially L shape one side of which extends in the vertical direction and the other side of which extends in the horizontal direction, and a bar-like second member extending vertically downwardly from the portion of the first member which extends in the horizontal direction. The fifth joint portion 5311e is fixedly connected at a proximal end thereof to a neighboring upper end of a part extending the first member of the fifth link 5313e in the vertical direction. The sixth joint portion 5311f is connected to proximal end (lower end) of the second member of the fifth link 5313e.

The sixth joint portion 5311f has a substantially columnar shape and supports, at a distal end side thereof, a proximal end of the fifth link 5313e for rotation around an axis of rotation (sixth axis O₆) parallel to the vertical direction. The sixth link 5313f is fixedly connected at a distal end thereof to a proximal end of the sixth joint portion 5311f.

The sixth link 5313f is a bar-like member extending in the vertical direction and is fixedly connected at a proximal end thereof to an upper face of the base unit 5315.

The first joint portion 5311a to sixth joint portion 5311f have movable ranges suitably set such that the microscope unit 5303 can make a desired movement. Consequently, in the arm unit 5309 having the configuration described above, a movement of totaling six degrees of freedom including three degrees of freedom for translation and three degrees of freedom for rotation can be implemented with regard to a movement of the microscope unit 5303. By configuring the arm unit 5309 such that six degrees of freedom are implemented for movements of the microscope unit 5303 in this manner, the position and the posture of the microscope unit 5303 can be controlled freely within the movable range of the arm unit 5309. Accordingly, it is possible to observe a surgical region from every angle, and surgery can be executed more smoothly.

It is to be noted that the configuration of the arm unit 5309 as depicted is an example at all, and the number and shape (length) of the links including the arm unit 5309 and the number, location, direction of the axis of rotation and so forth of the joint portions may be designed suitably such that desired degrees of freedom can be implemented. For example, in order to freely move the microscope unit 5303, preferably the arm unit 5309 is configured so as to have six degrees of freedom as described above. However the arm unit 5309 may also be configured so as to have much greater degree of freedom (namely, redundant degree of freedom). Where a redundant degree of freedom exists, it is possible to change the posture of the arm unit 5309 in a state in which the position and the posture of the microscope unit 5303 are fixed. Accordingly, control can be implemented which is higher in convenience to the surgeon such as to control the posture of the arm unit 5309 such that, for example, the arm unit 5309 does not interfere with the field of view of the surgeon who watches the display apparatus 5319.

Here, an actuator in which a driving mechanism such as a motor, an encoder which detects an angle of rotation at each joint portion and so forth are incorporated may be provided for each of the first joint portion 5311a to sixth joint portion 5311f. By suitably controlling driving of the actuators provided in the first joint portion 5311a to sixth joint portion 5311f by the control apparatus 5317, the posture of the arm unit 5309, namely, the position and the posture of the microscope unit 5303, can be controlled. Specifically, the control apparatus 5317 can comprehend the posture of the arm unit 5309 at present and the position and the posture of the microscope unit 5303 at present on the basis of information regarding the angle of rotation of the joint portions detected by the encoders. The control apparatus 5317 uses the comprehended information to calculate a control value (for example, an angle of rotation or torque to be generated) for each joint portion with which a movement of the microscope unit 5303 in accordance with an operation input from the user is implemented. Accordingly the control apparatus 5317 drives driving mechanism of the each joint portion in accordance with the control value. It is to be noted that, in this case, the control method of the arm unit 5309 by the control apparatus 5317 is not limited, and various known control methods such as force control or position control may be applied.

For example, when the surgeon performs operation inputting suitably through an inputting apparatus not depicted, driving of the arm unit 5309 may be controlled suitably in response to the operation input by the control apparatus 5317 to control the position and the posture of the microscope unit 5303. By this control, it is possible to support, after the microscope unit 5303 is moved from an arbitrary position to a different arbitrary position, the microscope unit 5303 fixedly at the position after the movement. It is to be noted that, as the inputting apparatus, preferably an inputting apparatus is applied which can be operated by the surgeon even if the surgeon has a surgical tool in its hand such as, for example, a foot switch taking the convenience to the surgeon into consideration. Further, operation inputting may be performed in a contactless fashion on the basis of gesture detection or line-of-sight detection in which a wearable device or a camera which is provided in the surgery room is used. This makes it possible even for a user who belongs to a clean area to operate an apparatus belonging to an unclean area with a high degree of freedom. In addition, the arm unit 5309 may be operated in a master-slave fashion. In this case, the arm unit 5309 may be remotely controlled by the user through an inputting apparatus which is placed at a place remote from the surgery room.

Further, where force control is applied, the control apparatus 5317 may perform power-assisted control to drive the actuators of the first joint portion 5311a to sixth joint portion 5311f such that the arm unit 5309 may receive external force by the user and move smoothly following the external force. This makes it possible to move, when the user holds and directly moves the position of the microscope unit 5303, the microscope unit 5303 with comparatively weak force. Accordingly, it becomes possible for the user to move the microscope unit 5303 more intuitively by a simpler and easier operation, and the convenience to the user can be improved.

Further, driving of the arm unit 5309 may be controlled such that the arm unit 5309 performs a pivot movement. The pivot movement here is a motion for moving the microscope unit 5303 such that the direction of the optical axis of the microscope unit 5303 is kept toward a predetermined point (hereinafter referred to as pivot point) in a space. Since the pivot movement makes it possible to observe the same observation position from various directions, more detailed observation of an affected area becomes possible. It is to be noted that, where the microscope unit 5303 is configured such that the focal distance thereof is fixed, preferably the pivot movement is performed in a state in which the distance between the microscope unit 5303 and the pivot point is fixed. In this case, the distance between the microscope unit 5303 and the pivot point may be adjusted to a fixed focal distance of the microscope unit 5303 in advance. By the configuration just described, the microscope unit 5303 comes to move on a hemispherical plane (schematically depicted in FIG. 10) having a diameter corresponding to the focal distance centered at the pivot point, and even if the observation direction is changed, a clear picked up image can be obtained. On the other hand, where the microscope unit 5303 is configured such that the focal distance thereof is adjustable, the pivot movement may be performed in a state in which the distance between the microscope unit 5303 and the pivot point is variable. In this case, for example, the control apparatus 5317 may calculate the distance between the microscope unit 5303 and the pivot point on the basis of information regarding the angles of rotation of the joint portions detected by the encoders and automatically adjust the focal distance of the microscope unit 5303 on the basis of a result of the calculation. Alternatively, where the microscope unit 5303 includes an AF function, adjustment of the focal distance may be performed automatically by the AF function every time the changing in distance caused by the pivot movement between the microscope unit 5303 and the pivot point.

Further, each of the first joint portion 5311a to sixth joint portion 5311f may be provided with a brake for constraining the rotation of the first joint portion 5311a to sixth joint portion 5311f. Operation of the brake may be controlled by the control apparatus 5317. For example, if it is intended to fix the position and the posture of the microscope unit 5303, then the control apparatus 5317 renders the brakes of the joint portions operative. Consequently, even if the actuators are not driven, the posture of the arm unit 5309, namely, the position and posture of the microscope unit 5303, can be fixed, and therefore, the power consumption can be reduced. When it is intended to move the position and the posture of the microscope unit 5303, the control apparatus 5317 may release the brakes of the joint portions and drive the actuators in accordance with a predetermined control method.

Such operation of the brakes may be performed in response to an operation input by the user through the operation unit 5307 described hereinabove. When the user intends to move the position and the posture of the microscope unit 5303, the user would operate the operation unit 5307 to release the brakes of the joint portions. Consequently, the operation mode of the arm unit 5309 changes to a mode in which rotation of the joint portions can be performed freely (all-free mode). On the other hand, if the user intends to fix the position and the posture of the microscope unit 5303, then the user would operate the operation unit 5307 to render the brakes of the joint portions operative. Consequently, the operation mode of the arm unit 5309 changes to a mode in which rotation of the joint portions is constrained (fixed mode).

The control apparatus 5317 integrally controls operation of the microscopic surgery system 5300 by controlling operation of the microscope apparatus 5301 and the display apparatus 5319. For example, the control apparatus 5317 renders the actuators of the first joint portion 5311a to sixth joint portion 5311f operative in accordance with a predetermined control method to control driving of the arm unit 5309. Further, for example, the control apparatus 5317 controls operation of the brakes of the first joint portion 5311a to sixth joint portion 5311f to change the operation mode of the arm unit 5309. Further, for example, the control apparatus 5317 performs various signal processes for an image signal acquired by the image pickup unit of the microscope unit 5303 of the microscope apparatus 5301 to generate image data for display and controls the display apparatus 5319 to display the generated image data. As the signal processes, various known signal processes such as, for example, a development process (demosaic process), an image quality improving process (a bandwidth enhancement process, a super-resolution process, a noise reduction (NR) process and/or an image stabilization process) and/or an enlargement process (namely, an electronic zooming process) may be performed.

It is to be noted that communication between the control apparatus 5317 and the microscope unit 5303 and communication between the control apparatus 5317 and the first joint portion 5311a to sixth joint portion 5311f may be wired communication or wireless communication. Where wired communication is applied, communication by an electric signal may be performed or optical communication may be performed. In this case, a cable for transmission used for wired communication may be configured as an electric signal cable, an optical fiber or a composite cable of them in response to an applied communication method. On the other hand, where wireless communication is applied, since there is no necessity to lay a transmission cable in the surgery room, such a situation that movement of medical staff in the surgery room is disturbed by a transmission cable can be eliminated.

The control apparatus 5317 may be a processor such as a central processing unit (CPU) or a graphics processing unit (GPU), or a microcomputer or a control board in which a processor and a storage element such as a memory are incorporated. The various functions described hereinabove can be implemented by the processor of the control apparatus 5317 operating in accordance with a predetermined program. It is to be noted that, in the example depicted, the control apparatus 5317 is provided as an apparatus separate from the microscope apparatus 5301. However, the control apparatus 5317 may be installed in the inside of the base unit 5315 of the microscope apparatus 5301 and configured integrally with the microscope apparatus 5301. The control apparatus 5317 may also include a plurality of apparatus. For example, microcomputers, control boards or the like may be disposed in the microscope unit 5303 and the first joint portion 5311a to sixth joint portion 5311f of the arm unit 5309 and connected for communication with each other to implement functions similar to those of the control apparatus 5317.

The display apparatus 5319 is provided in the surgery room and displays an image corresponding to image data generated by the control apparatus 5317 under the control of the control apparatus 5317. In other words, an image of a surgical region picked up by the microscope unit 5303 is displayed on the display apparatus 5319. The display apparatus 5319 may display, in place of or in addition to an image of a surgical region, various kinds of information relating to the surgery such as physical information of a patient or information regarding a surgical procedure of the surgery. In this case, the display of the display apparatus 5319 may be switched suitably in response to an operation by the user. Alternatively, a plurality of such display apparatus 5319 may also be provided such that an image of a surgical region or various kinds of information relating to the surgery may individually be displayed on the plurality of display apparatus 5319. It is to be noted that, as the display apparatus 5319, various known display apparatus such as a liquid crystal display apparatus or an electro luminescence (EL) display apparatus may be applied.

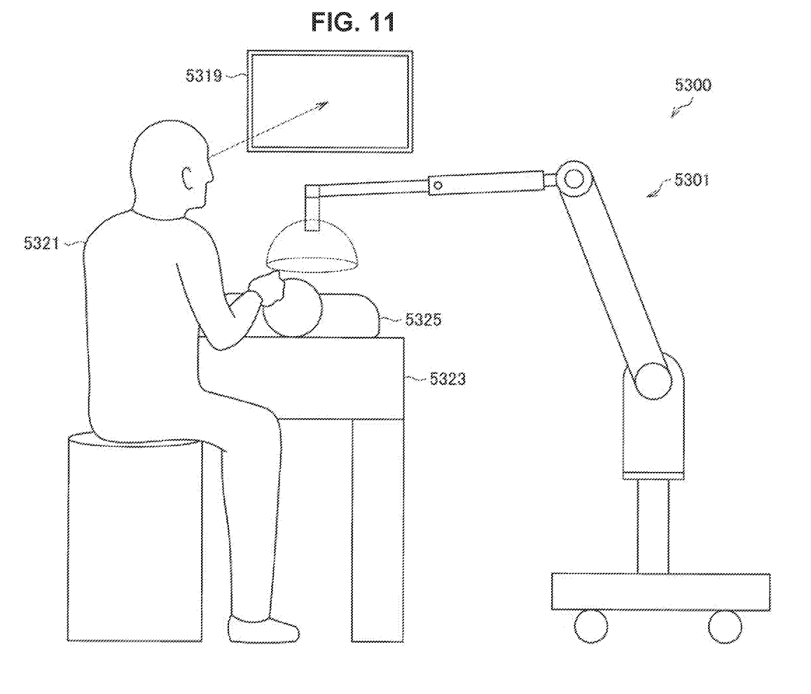

FIG. 11 is a view illustrating a state of surgery in which the microscopic surgery system 5300 depicted in FIG. 10 is used. FIG. 11 schematically illustrates a state in which a surgeon 5321 uses the microscopic surgery system 5300 to perform surgery for a patient 5325 on a patient bed 5323. It is to be noted that, in FIG. 11, for simplified illustration, the control apparatus 5317 from among the components of the microscopic surgery system 5300 is omitted and the microscope apparatus 5301 is depicted in a simplified from.

As depicted in FIG. 11, upon surgery, using the microscopic surgery system 5300, an image of a surgical region picked up by the microscope apparatus 5301 is displayed in an enlarged scale on the display apparatus 5319 installed on a wall face of the surgery room. The display apparatus 5319 is installed at a position opposing to the surgeon 5321, and the surgeon 5321 would perform various treatments for the surgical region such as, for example, resection of the affected area while observing a state of the surgical region from a video displayed on the display apparatus 5319.

An example of the microscopic surgery system 5300 to which the technology according to an embodiment of the present disclosure can be applied has been described. It is to be noted here that, while the microscopic surgery system 5300 is described as an example, the system to which the technology according to an embodiment of the present disclosure can be applied is not limited to this example. For example, the microscope apparatus 5301 may also function as a supporting arm apparatus which supports, at a distal end thereof, a different observation apparatus or some other surgical tool in place of the microscope unit 5303. As the other observation apparatus, for example, an endoscope may be applied. Further, as the different surgical tool, forceps, a pair of tweezers, a pneumoperitoneum tube for pneumoperitoneum or an energy treatment tool for performing incision of a tissue or sealing of a blood vessel by cautery and so forth can be applied. By supporting any of such an observation apparatus and surgical tools as just described by the supporting apparatus, the position of them can be fixed with a high degree of stability in comparison with that in an alternative case in which they are supported by hands of medical staff. Accordingly, the burden on the medical staff can be reduced. The technology according to an embodiment of the present disclosure may be applied to a supporting arm apparatus which supports such a component as described above other than the microscopic unit.

### 4. MODIFIED EXAMPLES

The preferred embodiment of the present disclosure has been described above with reference to the accompanying drawings, whilst the present disclosure is not limited to the above examples. A person skilled in the art may find various alterations and modifications within the scope of the appended claims, and it should be understood that they will naturally come under the technical scope of the present disclosure.

For example, the configuration according to the present embodiment is not limited to the example illustrated in FIG. 4. As an example, in place of the CCU 139, the light source control unit 206 may be provided within the light source apparatus 143. In this case, the CCU 139 can provide the determined line numbers of the top line and the bottom line to the light source apparatus 143. (The light source control unit 206 in) the light source apparatus 143 can then control irradiation of light on the basis of the provided line numbers of the top line and the bottom line.

Further, the respective steps in operation of the above-described embodiment do not have to be necessarily processed in the described order. For example, the respective steps may be processed in order which has been changed as appropriate. Further, the respective steps may be processed partially in parallel or individually instead of being processed in chronological order. Further, part of the described steps may be omitted or another step may be further added.

Further, according to the above-described embodiment, it is also possible to provide a computer program for causing hardware such as a processor such as a CPU and a GPU and a storage element such as a memory to exert functions equivalent to those of the respective components of the CCU 139 according to the above-described embodiment. Further, a storage medium in which the computer program is recorded is also provided.

Further, the effects described in this specification are merely illustrative or exemplified effects, and are not limitative. That is, with or in the place of the above effects, the technology according to the present disclosure may achieve other effects that are clear to those skilled in the art from the description of this specification.

Additionally, the present technology may also be configured as below.

(1)

A control apparatus including:

a light source control unit configured to determine a period in accordance with a period between an exposure start timing of a first line in an image pickup element and an exposure end timing of a second line in the image pickup element as an irradiation period during which a light source unit is caused to radiate light,

in which the second line is a line in which start of exposure in one frame is earlier than in the first line.

(2)

The control apparatus according to (1),

in which the light source control unit determines a period between the exposure start timing of the first line and the exposure end timing of the second line as the irradiation period.

(3)

The control apparatus according to (2),

in which the exposure end timing of the second line is a timing at which an exposure period of the second line has elapsed since an exposure start timing of the second line.

(4)

The control apparatus according to any one of (1) to (3),

in which the light source control unit determines a same length of the irradiation period for each frame.

(5)

The control apparatus according to any one of (1) to (4), further including: a line determining unit configured to determine the first line and the second line on the basis of a predetermined criterion.

(6)

The control apparatus according to (5),

in which the line determining unit changes the first line or the second line on the basis of change of a value indicated by the predetermined criterion, and in a case where the first line or the second line is changed, the light source control unit changes a length of the irradiation period on the basis of the changed first line and the changed second line.

(7)

The control apparatus according to (5) or (6),

in which the predetermined criterion includes zoom information of an image pickup unit including the image pickup element.

(8)

The control apparatus according to any one of (5) to (7),

in which the predetermined criterion includes scope information of an endoscope including the image pickup element.

(9)

The control apparatus according to any one of (5) to (8),

in which the predetermined criterion includes information of a mask region in an image picked up by an image pickup unit including the image pickup element.

(10)

The control apparatus according to (9),

in which the information of the mask region is specified on the basis of scope information of an endoscope including the image pickup unit.

(11)

The control apparatus according to (9),

in which the information of the mask region is specified through a predetermined image process on an image picked up by the image pickup unit.

(12)

The control apparatus according to any one of (1) to (11),

in which the light source control unit further causes the light source unit to radiate light during the irradiation period for each frame.

(13)

The control apparatus according to (12),

in which the light source control unit does not cause the light source unit to radiate light during a period other than the irradiation period.

(14)

The control apparatus according to (13),

in which the light source control unit causes the light source unit to alternately radiate first light and second light for each frame.

(15)

The control apparatus according to (14),

in which the first light is white light, and the second light is special light.

(16)

The control apparatus according to (13),

in which the light source control unit causes the light source unit to radiate a same type of light for each frame.

(17)

The control apparatus according to any one of (1) to (16),

in which the light source unit is a laser light source.

(18)

The control apparatus according to any one of (1) to (17),

in which the light source unit is a semiconductor light source.

(19)

A control system including:

a light source unit;

an image pickup unit; and

a light source control unit configured to determine a period in accordance with a period between an exposure start timing of a first line in an image pickup element included in the image pickup unit and an exposure end timing of a second line in the image pickup element as an irradiation period during which the light source unit is caused to radiate light,

in which the second line is a line in which start of exposure in one frame is earlier than in the first line.

(20)

A control method including: determining, by a processor, a period in accordance with a period between an exposure start timing of a first line in an image pickup element and an exposure end timing of a second line in the image pickup element as an irradiation period during which a light source unit is caused to radiate light,

in which the second line is a line in which start of exposure in one frame is earlier than in the first line.

### REFERENCE SIGNS LIST

10 endoscopic surgery system
101 endoscope
105 camera head
107 lens unit
109 image pickup unit
111 driving unit
113 communication unit
115 camera head controlling unit
139 CCU
143 light source apparatus
200 signal processing unit
202 detecting unit
204 synchronization control unit
206 light source control unit

1. A control apparatus comprising:
a light source control unit configured to determine a period in accordance with a period between an exposure start timing of a first line in an image pickup element and an exposure end timing of a second line in the image pickup element as an irradiation period during which a light source unit is caused to radiate light,
wherein the second line is a line in which start of exposure in one frame is earlier than in the first line.

2. The control apparatus according to claim 1,
wherein the light source control unit determines a period between the exposure start timing of the first line and the exposure end timing of the second line as the irradiation period.

2. The control apparatus according to claim 2,
wherein the exposure end timing of the second line is a timing at which an exposure period of the second line has elapsed since an exposure start timing of the second line.

4. The control apparatus according to claim 1,
wherein the light source control unit determines a same length of the irradiation period for each frame.

5. The control apparatus according to claim 1, further comprising:
a line determining unit configured to determine the first line and the second line on a basis of a predetermined criterion.

6. The control apparatus according to claim 5,
wherein the line determining unit changes the first line or the second line on a basis of change of a value indicated by the predetermined criterion, and
in a case where the first line or the second line is changed, the light source control unit changes a length of the irradiation period on a basis of the changed first line and the changed second line.

7. The control apparatus according to claim 5,
wherein the predetermined criterion includes zoom information of an image pickup unit including the image pickup element.

8. The control apparatus according to claim 5,
wherein the predetermined criterion includes scope information of an endoscope including the image pickup element.

9. The control apparatus according to claim 5,
wherein the predetermined criterion includes information of a mask region in an image picked up by an image pickup unit including the image pickup element.

10. The control apparatus according to claim 9,
wherein the information of the mask region is specified on a basis of scope information of an endoscope including the image pickup unit.

11. The control apparatus according to claim 9,
wherein the information of the mask region is specified through a predetermined image process on an image picked up by the image pickup unit.

12. The control apparatus according to claim 1,
wherein the light source control unit further causes the light source unit to radiate light during the irradiation period for each frame.

13. The control apparatus according to claim 12,
wherein the light source control unit does not cause the light source unit to radiate light during a period other than the irradiation period.

14. The control apparatus according to claim 13,
wherein the light source control unit causes the light source unit to alternately radiate first light and second light for each frame.

15. The control apparatus according to claim 14,
wherein the first light is white light, and
the second light is special light.

16. The control apparatus according to claim 13,
wherein the light source control unit causes the light source unit to radiate a same type of light for each frame.

17. The control apparatus according to claim 1,
wherein the light source unit is a laser light source.

18. The control apparatus according to claim 1,
wherein the light source unit is a semiconductor light source.

19. A control system comprising:
a light source unit;
an image pickup unit; and
a light source control unit configured to determine a period in accordance with a period between an exposure start timing of a first line in an image pickup element included in the image pickup unit and an exposure end timing of a second line in the image pickup element as an irradiation period during which the light source unit is caused to radiate light,
wherein the second line is a line in which start of exposure in one frame is earlier than in the first line.

20. A control method comprising:
determining, by a processor, a period in accordance with a period between an exposure start timing of a first line in an image pickup element and an exposure end timing of a second line in the image pickup element as an irradiation period during which a light source unit is caused to radiate light,
wherein the second line is a line in which start of exposure in one frame is earlier than in the first line.
